(19) United States
(12) Patent Application Publication
(10) Pub. No.: US 2003/0117121 A1
(43) Pub. Date: Jun. 26, 2003

(54) High-side current-sense circuit for precision application

(76) Inventor: Daniel C. Prescott, Tustin, CA (US)

Correspondence Address: William S. Francos, Esq., VOLENTINE FRANCOS, PLLC, SUITE 150, 12200 SUNRISE VALLEY DRIVE, RESTON, VA, 20191, US

(21) Appl. No.: 10/032,142

(22) Filed: Dec. 20, 2001

(51) Int. Cl. G01R 23/17

(52) U.S. Cl. 324/76.36

(57) ABSTRACT

According to an exemplary embodiment of the present invention, an electrical circuit includes a device which has a high side current node. The electrical circuit also includes a current mirror circuit, which senses a current into said high-side node, and which includes at least one monolithic device.

### FIELD OF THE INVENTION

The present invention relates generally to a current-mirror circuit, and more particularly to a current-mirror circuit for high-side current sensing with high precision sensing capability in both high-voltage and low-voltage applications.

### BACKGROUND OF THE INVENTION

In certain applications, it is useful to reproduce the current in a particular device with high precision, to allow the monitoring and measurement of this current relative to ground potential. For example, in optoelectronic applications, utilizing certain detectors such as avalanche photodiodes (APD), the bias voltage can be relatively high, beyond the capabilities of many monolithic processes. In APD bias applications, it is useful to have a measure, or sense of the current representative of the current flowing through the APD device. However, it is often impractical to sense this current at the low-potential (near ground) contact of the APD. Therefore, it is necessary to sense the current at the high-voltage node of the detector.

One known technique used for current sensing is via a current source circuit known as a current-mirror circuit. Current-mirror circuits may be based on field effect transistor (FET technology), or on bipolar transistor technology. In either case, when an input current is supplied to an input node of the current mirror circuit, an output current proportional to the input current flows through the output node. This operation is analogous to the reflection of light from a mirror. Hence, a current sense circuit of this kind is often referred to as a current mirror circuit. While current mirror circuits may be used in the sensing of the photocurrent of a photo-detector (e.g. APD) there are certain drawbacks to conventional current-mirror sensing techniques and circuits.

One conventional solution to high-side current sensing is the use of a current-mirror circuit which includes a matched bipolar (e.g. pnp) transistor pair. A photodiode-bias current-sense circuit of this type requires a high voltage transistor to isolate the aforementioned low voltage matched transistor from the full voltage supply. This conventional technique also requires a biasing network to maintain a sense-side collector-to-emitter voltage below the breakdown voltage of the low-voltage matched transistor pair. Moreover, it is common to use negative feedback (emitter resistors) in the current mirror circuit to reduce the dependence of the accuracy on the matching of the base-emitter junction voltages in the mirror transistors.

While the above bipolar current mirror circuit has shown promise in monitoring the current of the APD, the accuracy in the matching is less than acceptable in many precision applications. Moreover, additional errors due to the tolerances of the negative feedback resistors further exacerbate the inaccuracy.

As can be appreciated, the inaccuracy of conventional current sensing circuits described above can be even more pronounced at higher temperatures and voltages, especially over the dynamic range dictated by the APD bias application.

What is needed, therefore, is a current sensing device which overcomes at least the drawbacks of the conventional approaches described above.

### SUMMARY OF THE INVENTION

According to an exemplary embodiment of the present invention, an electrical circuit includes a device which has a high side current node. The electrical circuit also includes a current mirror circuit, which senses a current through the high-side node, and which includes at least one monolithic device.

### BRIEF DESCRIPTION OF THE DRAWINGS

The invention is best understood from the following detailed description when read with the accompanying drawing figures. It is emphasized that the various features are not necessarily drawn to scale. In fact, the dimensions may be arbitrarily increased or decreased for clarity of discussion.

FIG. 1 is a schematic diagram of a high-side current sense circuit connected to a photo-detector and transimpedance amplifier in accordance with an exemplary embodiment of the present invention.

FIG. 2 is a schematic diagram of a high-side current sense circuit connected to a photo-detector and transimpedance amplifier in accordance with another exemplary embodiment of the present invention.

### DETAILED DESCRIPTION

In the following detailed description, for purposes of explanation and not limitation, exemplary embodiments disclosing specific details are set forth in order to provide a thorough understanding of the present invention. However, it will be apparent to one having ordinary skill in the art having had the benefit of the present disclosure, that the present invention may be practiced in other embodiments that depart from the specific details disclosed herein. Moreover, descriptions of well-known devices, methods and materials may be omitted so as to not obscure the description of the present invention.

Briefly, in accordance with an exemplary embodiment of the present invention to a current sensing circuit includes a current-mirror circuit for high-side sensing applications in which one side of the current mirror is a relatively high precision device, illustratively a monolithic device. Beneficially, the accuracy and reduced power of the monolithic device is coupled with high voltage discrete components enabling high-side current sensing with substantially improved precision relative to conventional current sensing circuits and techniques. Illustratively, the monolithic device is an operational amplifier (op-amp) which is selectively controlled to operate at a relatively low voltage in a high-voltage current mirror circuit.

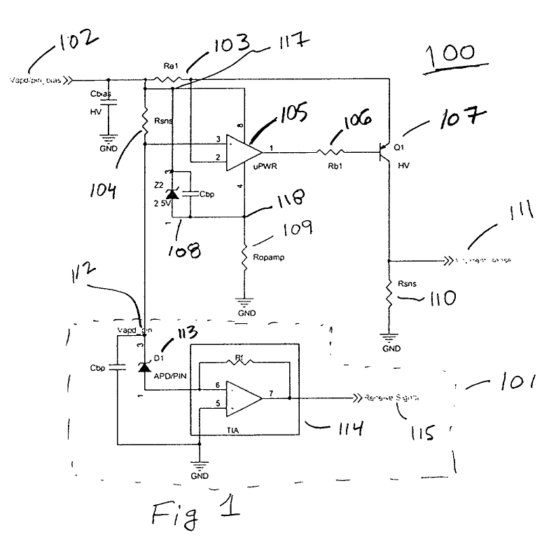

Turning to FIG. 1, a high-side current sensing circuit 100 in accordance with an exemplary embodiment of the present invention is shown. The current sensing circuit 100 is illustratively connected to an optical receiver circuit 101 which includes a photodetector 113 such as avalanche photodiode (APD) or a PIN photodiode. A transimpedance amplifier 114 is used to amplify the photocurrent from the photodetector 113 to a useful output receive signal 115.

In many optical communications applications, the photodetector 113 dictated by the application is an avalanche photodiode, which is operated at a relatively high voltage. For example, the avalanche photodiodes commonly used in the optical communications industry may have bias voltages of +80V and higher. Often, it is useful to monitor the photocurrent of the photodetector. This monitoring may be necessary to comply with a standard, or may be used for calibration by the end-user. Of course, there are other reasons to monitor the photocurrent of the photodetector.

Whether the photodetector 113 is a high-voltage bias APD, or a relatively low voltage bias PIN photodiode, it is useful to monitor the high-side current, for example the current into node 112. To wit, it is often impractical to monitor the photocurrent at any other point of the circuit, particularly at the ground-potential side of the photodetector. As such, it is useful to have a high-side current sensor. However, it is also required that the current sense circuit be relatively precise. For instance, in order to accurately adjust the APD bias voltage to obtain a desired avalanche multiplication factor (M), it is necessary to have a measure of the photocurrent with an accuracy of less than a few percent over the full dynamic range of the detector.

In the present exemplary embodiment, a bias voltage 102 biases photodetector 113 during operation. For purposes of illustration, it is assumed that the bias voltage 102 is relatively high (e.g. for an APD), but it is clearly understood that the high-side current sense circuit 100 in accordance with an exemplary embodiment of the present invention could be used in conjunction with relatively low bias voltage applications; for example in the case that photodetector 113 were a PIN photodiode.

As will become clearer as the present discussion proceeds, a current mirror circuit is established with a high-side sense resistor (R_{SNS}) 104 being one side of the current mirror; while a high voltage transistor 107 and emitter resistor (Rₑₗ) 103 comprise the other side of the current mirror. It is noted that the voltage rating of the high-voltage transistor(s) can be as high as is dictated by the application; illustratively the voltage rating is 300V or greater. It is further noted that the current through the high-side sense resistor 104 and that through a low-side sense resistor 110 are ratiometrically equivalent, with the ratio Iₛₙₛ/Iₑ=Rₑₗ/Rₛₙₛ, where Iₛₙₛ is the current through the high-side sense resistor 104, and Iₑ is the current through low-side sense resistor 110.

As mentioned, a bias voltage 102 is input to the high-side current sense circuit 100. Bias voltage 102 undergoes an insubstantial drop across the high-side sense resistor 104, and can be on the order of 80V (and higher) at node 112. Of course, the current through the high-side sense resistor is substantially identical to the photocurrent of photodetector 113, given that the input bias currents to the operational amplifier 105 are negligible. An operational amplifier 105 is used in the current mirror circuit to bias the high voltage transistor 107 via base resistor 106, in order to balance the currents in Rₛₙₛ 104 and Rₑₗ 103. The op-amp 105 is a monolithic device, illustratively a micropower, rail-to-rail input, op-amp.

The op-amp 105 can be selected to be a relatively high precision, low power device, thus enabling the advantageous precision of the high-side current sense circuit 100 of the exemplary embodiment. As can be appreciated by one of ordinary skill in the art, it is necessary to clamp the voltage across the op-amp between the specified minimum and maximum operating voltages. Illustratively, the minimum and maximum operating voltages of op-amp 105 are on the order of 2.5V and 6.0V, respectively. In accordance with the present exemplary embodiment, the clamping of the voltage across the op-amp 105 is effected using a zener diode circuit 108. The zener diode circuit 108 is comprised of a zener diode (e.g., a 2.5V to 3.0V zener diode) in parallel with a bypass capacitor (Cbp). This parallel combination is in series with resistor Rₒₚₐₘₚ 109, the aggregation of which constitutes a linear shunt regulator. As such, while the voltage at node 117 may have an absolute value on the order of 100V, the voltage differential between node 117 and node 118 is merely the zener diode breakdown voltage, which is illustratively 2.5V to 3.0V.

The zener diode circuit 108 thus enables a precision op-amp such as op-amp 105 to be used in a relatively high voltage application. Of course, the op-amp resistor (R_{OPAMP}) 109 is necessarily a relatively high resistance value since the majority of the voltage drop between node 118 and ground is across the op-amp resistor 109, thus resulting in low power dissipation. Finally, it is noted that the use of the zener diode circuit 108 as a voltage clamp is merely illustrative. For example, an avalanche diode circuit could be used in place of the zener diode circuit to effect the desired clamping. Still other clamping techniques within the purview of one of ordinary skill in the art having had the benefit of the present disclosure could be used to achieve the desired end.

In operation, the inputs to the op-amp 105 will be virtually equal; the predominant difference therebetween being the specified input offset voltage of the particular operational amplifier, which may be chosen to be arbitrarily small, for precision. Any additional difference between the inputs will be amplified, resulting in a change in the output voltage of the op amp, thus adjusting the transistor bias to a level where the currents through Rₛₙₛ 104 and Rₑₗ 103 are balanced and the op amp inputs are equalized, within the tolerance allowed by the precision of the input-offset voltage and the tolerance of Rₛₙₛ 104 and Rₑₗ 103.

In the present exemplary embodiment, the high-side sense resistor (Rₛₙₛ) 104 and the emitter resistor (Rₑₗ) 103 are matched in tolerance and preferably value. It is noted that this can induce a maximum error of approximately 2% due to the initial tolerance of standard 1% resistors. This can be reduced through the employment of higher precision resistors. It is noted that (resistors of the same value are likely to be from the same process batch, thus resulting in much tighter matching in value and temperature coefficient.) Moreover, the impact of the input-offset voltage of the op-amp can be reduced by increasing the value of the high side resistor, 104. Finally, it is noted that the low side transimpedance resistor 110 is useful in converting the mirrored current (through transistor 107) to a voltage 111, proportional to the actual photodiode current, which may be used to ultimately measure the sensed photocurrent.

The above devices are merely illustrative of an exemplary embodiment of the present invention. In addition to the alternatives previously described, it is noted that high voltage pnp transistor 107 could be replaced by a p-channel enhancement-mode, field effect transistor (PMOS FET). This may be advantageous as the base current of the high-voltage transistor 107 can induce a maximum error of approximately 2%.

From the above description, it is clear that a current-mirror circuit, which is of relatively high precision may be implemented in high-side current sense measurements with significant precision by virtue of the micropower op-amp 105 which is clamped to a low supply voltage by the zener diode circuit 108. Ultimately, this enables the measurement of the mirrored photocurrent relative to ground potential.

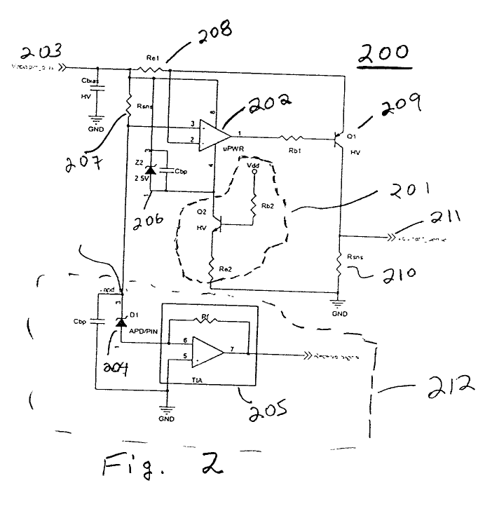

Turning to FIG. 2, a high-side current-sense circuit 200 in accordance with another exemplary embodiment is shown. The high-side current sense circuit 200 of the presently described exemplary embodiment bears a great deal of similarity to the high-side current sense circuit 100 shown in FIG. 1. As such, many of the similarities therebetween will not be repeated in the interest of brevity, and only distinctions between the circuits will be described in detail.

The high-side current sense circuit 200 illustratively measures the photocurrent of an optical receiver circuit 212. The high-side current sense circuit 200 includes a constant current source 201 for biasing op-amp 202. This constant-current source 201 is a standard bipolar current source, and usefully replaces R_{OPAMP} (109 in FIG. 1). Again, in operation, a bias voltage 203 is input to high-side current sense circuit 200. Bias voltage 203 biases the photodetector 204 which inputs photocurrent to a transimpedance amplifier 205 as previously described. As described previously, a zener diode circuit 206 is used to clamp the voltage across the op-amp 202. Moreover, as was also previously described, a current mirror circuit is illustratively comprised of a high-side current sense resistor (R_{SNS}) 207 on one side; an emitter resistor 208 and high voltage transistor 209. The low-side transimpedance resistor 210 usefully enables the conversion of the sensed current to a voltage which is output at 211. Finally, op-amp 202 operates at substantially low voltage, but with high precision, and usefully biases the high voltage transistor 209.

In applications which dictate a relatively narrow dynamic range for the bias voltage 102 (for instance, an application which biases an APD which can vary from 25V to 35V in breakdown voltage), the embodiment of FIG. 1 is adequate due to the narrow range of voltage across Rₒₚₐₘₚ. The power dissipated by Rₒₚₐₘₚ will be ((V_{bias}−V_{zener})² Rₒₚₐₘₚ). However, in applications requiring a wide dynamic range of bias voltage 203, (for instance, a circuit supporting both 5V PIN as well as 35V APD applications) it is beneficial to implement the shunt regulator (powering the opamp) with a current source 201, to minimize power dissipated in the op amp bias circuit. The power dissipated by this circuit will be (V_{bias}−V_{zener})*I_{bias}, where I_{bias} should be slightly greater than that required by opamp 202 for operation.

The invention having been described in detail in connection through a discussion of exemplary embodiments, it is clear that various modifications of the invention will be apparent to one having ordinary skill in the art having had the benefit of the present disclosure. Such modifications and variations are included within the scope of the appended claims.

I claim:

1. An electrical circuit, comprising:
a device having a high-side voltage node; and
a current mirror circuit which senses a current into said high-side voltage node, and which includes at least one monolithic device.

2. An electrical circuit as recited in claim 1, wherein said current mirror circuit is comprised of a first side which includes a first resistor, and a second side which includes a transistor and a second resistor.

3. An electrical circuit as recited in claim 2, wherein said transistor is a high-voltage transistor.

4. An electrical circuit as recited in claim 1, wherein said device is a photodetector.

5. An electrical device as recited in claim 4, wherein said photodetector is an element of an optical receiver circuit.

6. An electrical circuit as recited in claim 4, wherein said photodetector is a PIN photodiode.

7. An electrical circuit as recited in claim 4, wherein said photodetector is an avalanche photodiode (APD).

8. An electrical circuit as recited in claim 2, wherein a current through said first resistor is substantially equal to said current, and said current is substantially equal to a current through said device.

9. An electrical circuit as recited in claim 8, wherein device is a photodiode said current though said device is a photocurrent.

10. An electrical circuit as recited in claim 1, wherein a voltage across said monolithic device is clamped to a predetermined level.

11. An electrical circuit as recited in claim 10, wherein said monolithic device is an operational amplifier.

12. An electrical circuit as recited in claim 10, wherein said clamping of said voltage is effected by a zener diode circuit.

13. An electrical circuit as recited in claim 12, wherein said zener diode circuit is in series with a resistor, forming a shunt regulator.

14. An electrical circuit as recited in claim 10, wherein a constant current source biases said operational amplifier.

15. An electrical circuit as recited in claim 1, wherein said current mirror circuit senses said current with an accuracy of 2% or less.

16. An electrical circuit as recited in claim 10, wherein said clamping of said voltage is effected by an avalanche diode circuit.
